(19) United States
(12) Patent Application Publication
(10) Pub. No.: US 2016/0141482 A1
(43) Pub. Date: May 19, 2016

(54) Manufacturing Process of the Thermoelectric Conversion Element

(71) Applicant: National Tsing Hua University, Hsinchu (TW)

(72) Inventors: Zung-Hang WEI, Hsinchu City (TW); Hao-Ting HUANG, Hsinchu City (TW)

(21) Appl. No.: 14/855,052

(22) Filed: Sep. 15, 2015

(30) Foreign Application Priority Data
Nov. 13, 2014 (TW) 103139431

(51) Int. Cl. H01L 35/34; H01L 35/30

(52) U.S. Cl. CPC H01L 35/34; H01L 35/30

(57) ABSTRACT

A manufacturing process of a thermoelectric conversion element is provided, which is characterized of applying the semiconductor technology to construct the thermoelectric conversion element with a nano/micro gap to reduce the heat conduction coefficient of the thermoelectric conversion element, so as to significantly enhance the thermoelectric conversion efficiency of the thermoelectric conversion element. In addition, by adding a nano additive in the nano/micro gap of the thermoelectric conversion element, the conductivity of the thermoelectric conversion element can be increased and the efficiency of the heat power conversion can further be promoted.

### CROSS-REFERENCE TO RELATED APPLICATION

This application claims priority from Taiwan Patent Application No. 103139431, filed on Nov. 13, 2014, in the Taiwan Intellectual Property Office, the content of which are hereby incorporated by reference in their entirety for all purposes.

### BACKGROUND OF THE INVENTION

1. Field of the Invention

This present disclosure relates to a manufacturing process of a thermoelectric conversion element, and more particularly, to the thermoelectric conversion element having a nano/micro gap. The structure of the nano/micro gap can enhance the thermoelectric conversion efficiency of the thermoelectric conversion element. The present disclosure also describe the variance of the energy conversion efficiency of the thermoelectric conversion element upon adding nano particles of different gaps in the nano/micro gap.

2. Description of the Related Art

Because of the severe consumption of global initial energy and the serious greenhouse effect, the development and application of renewable energy resources have become an issue of great urgency. The technology of thermoelectric conversion is to convert the heat energy of an initial energy into the more valuable electric energy. Additionally, as there are no movable member operated during the process of the conversion, productions of noise and other by-products are evitable. Therefore, the renewable energy resources belong to the green power which matches the concept of environmental protection.

Conventionally, the semiconductor materials are served as the substrate and then a certain proportions or various types of the rare-earth elements are doped to adjust the effective electron concentration in the semiconductor materials, and the mainstream study is to increase the conductivity σ for improving the figure of merit ZT. However, doping the rare-earth element to adjust the conductivity still has the technical bottleneck. For example, firstly, it is not easy to get the rare-earth element and price thereof is expensive. Secondly, the uniformity of the doping cannot be controlled easily, and finally, the manufacturing process is complicated. Hence, the factors disable the current thermoelectric conversion element from being popularized.

The coefficients such as conductivity σ, Seebeck coefficient S, thermal conductivity coefficient k, and so on may be affected due to the change of material properties of band structure, band gap and density of state (DOS). The aforementioned material properties may be varied as the differences of the size and the growing cross-sectional direction.

In conclusion, the inventor of the invention has been mulling the technical problems and designs a manufacturing process of the thermoelectric conversion element and an application thereof which is aimed at improving the current drawbacks and further to increase industrial applicability.

### SUMMARY OF THE INVENTION

In view of the aforementioned technical problems, the objective of the invention is to provide a manufacturing process of the thermoelectric conversion element which is characterized by the use of semiconductor technology to construct nanostructures with nano gap to reduce the heat conduction properties of the thermoelectric conversion elements. Additionally, variance of the energy conversion efficiency of the thermoelectric conversion elements caused by adding nano particles in different nanoscale gaps is also discussed hereinafter.

In view of the aforementioned technical problems, purpose of the present disclosure is to provide a manufacturing process of the thermoelectric conversion element which is characterized by the use of semiconductor technology to simply the complicated manufacturing process of the conventional thermoelectric conversion element.

In view of the aforementioned technical problems, purpose of the present disclosure is to provide a manufacturing process of the thermoelectric conversion element which is characterized by the use of nano/micro gap to impede the heat conducting path of the materials such that the thermal conductivity coefficient k may be lowered to the least so as to promote the figure of merit ZT.

In view of the aforementioned technical problems, purpose of the present disclosure is to provide a manufacturing process of the thermoelectric conversion element which is characterized by adding a nano additive served as a medium for electrons jumping and being transmitted in the nano/micro gap so as to increase electrical conductivity of the thermoelectric conversion element and further enhance the figure of merit ZT.

In view of the aforementioned technical problems, purpose of the present disclosure is to provide a manufacturing process of the thermoelectric conversion element which is characterized by expanding the thermoelectric conversion element having nano gaps as an array structure. Moreover, adding nano additives in the nano/micro gaps in accordance with an alternate arrangement position of cold end and hot end tip structure may affect the energy conversion efficiency of the thermoelectric conversion elements.

According to the preceding purposes, a manufacturing process of a thermoelectric conversion element is provided, which includes the following steps. At least two nano/micro tip structures may be prepared, wherein tips of the at least two nano/micro tip structures may be partitioned with a nano/micro gap relatively, and connection electrodes may be respectively constructed at two sides opposing to the tips of the at least two nano/micro tip structures to enable the thermoelectric conversion element guiding an electrical energy converted from heat energy to use.

Preferably the tips of the at least two nano/micro tip structures may be arranged relatively or alternately to form the nano/micro gaps.

Preferably, a nano additive may be added in the nano/micro gap, and the nano additive may be served as a medium for electrons jumping and being transmitted so as to increase electrical conductivity of the thermoelectric conversion element.

Preferably, the nano additive may include nanoparticles, conductive media, organic particles, inorganic particles or a combination thereof.

In accordance with the aforementioned purpose, the present disclosure is further to provide a manufacturing process of a thermoelectric conversion element with a multi-dimensional nano/micro array which may include the following steps. A first nano/micro array structure and a second nano/micro array structure are prepared. A hot end electrode is constructed at a bottom of the first nano/micro array structure and a cold end electrode is constructed at a bottom of the second nano/micro array structure. The first nano/micro array structure and the second nano/micro array structure are arranged relatively or alternately, by nano/micro gaps such that the hot end electrode, the first nano/micro array structure, the second nano/micro array structure and the cold end electrode may form a current loop.

Preferably, the manufacturing process of a thermoelectric conversion element with a multi-dimensional nano/micro array in accordance with the present disclosure may further include adding nano additives in the nano/micro gaps, wherein the nano additives may be served as a medium for electrons jumping and being transmitted so as to increase electrical conductivity of the thermoelectric conversion element.

Preferably, the nano additive may include nanoparticles, conductive media, organic particles, inorganic particles or a combination thereof.

In accordance with the preceding purpose, the present disclosure is further to provide a thermoelectric conversion element with a multi-dimensional nano/micro array which may include a hot end electrode, a cold end electrode, a first nano/micro array structure and a second nano/micro array structure. The hot end electrode may be electrically connected to an external device, and the cold end electrode may be electrically connected to the external device. The first nano/micro array structure may be made of a thermoelectric material and may be disposed on the hot end electrode, and the second nano/micro array structure may be made of the thermoelectric material and may be disposed on the cold end electrode. The first nano/micro array structure and the second nano/micro array structure may be arranged relatively or alternately, by nano/micro gaps, and the external device may receive an electric current generated by a temperature variation of the thermoelectric conversion element with the multi-dimensional nano/micro array.

Preferably, the thermoelectric conversion element with the multi-dimensional nano/micro array in accordance with the present disclosure may further include adding nano additive in the nano/micro gaps, wherein the nano additive may be served as a medium for electrons jumping so as to increase electrical conductivity of the thermoelectric conversion element.

Preferably, the nano additive may include nanoparticles, conductive media, organic particles, inorganic particles or a combination thereof.

The primary purpose of the present disclosure is to provide a manufacturing process of a thermoelectric conversion element which may have one or more advantages as follows.

The first advantage is the breakthrough of the conventional thought. Compared with the conventional technique of doping various thermoelectric conversion elements or modifying the formation, aspect of the present disclosure is to use gaps to impede the heat conducting path of the thermoelectric materials to lower the heat conduction properties of thermoelectric conversion elements. This embodiment disclosed in the present disclosure is simple and easy to be applied and a creative technique is thereby provided to improve the energy conversion efficiency of the thermoelectric conversion elements.

The second advantage is the microminiaturized design. The thermoelectric conversion elements which have nanostructures with nano gap and are constructed by the semiconductor technology can be effectively integrated into the electronic components used in the semiconductor industry to expand the application thereof.

The third advantage is better energy conservation. As the thermoelectric conversion elements produced in accordance with the present disclosure is characterized of better figure of merit ZT, the waste heat is effectively converted into electric energy so as to reduce the burden caused by human and to reach to the purpose of saving energy.

The fourth advantage is cost reduction. Because the present disclosure is to utilize the nano/micro gap to construct the structure of the thermoelectric conversion element, the thermoelectric materials are no longer subjected to the rare-earth element such that the manufacturing cost can be reduced effectively.

### BRIEF DESCRIPTION OF THE DRAWINGS

Hereinafter, embodiments of the present disclosure will be described in detail with reference to the accompanying drawings so that those skilled in the art to which the present disclosure pertains can realize the present disclosure, wherein:

FIG. 1 is a flow chart of a manufacturing process of a thermoelectric conversion element in accordance with the present disclosure.

FIG. 2 is an experimental data diagram of a manufacturing process of a thermoelectric conversion element of the first embodiment in accordance with the present disclosure.

FIG. 3 is an experimental data diagram of a manufacturing process of a thermoelectric conversion element of the second embodiment in accordance with the present disclosure.

FIG. 4 is an experimental data diagram of a manufacturing process of a thermoelectric conversion element of the third embodiment in accordance with the present disclosure.

FIG. 5 is an experimental data diagram of a manufacturing process of a thermoelectric conversion element of the fourth embodiment in accordance with the present disclosure.

FIG. 6 is a flow chart of a manufacturing process of a thermoelectric conversion element with a multi-dimensional nano/micro array in accordance with the present disclosure.

FIG. 7 is a schematic diagram of a thermoelectric conversion element with a multi-dimensional nano/micro array in accordance with the present disclosure.

### DETAILED DESCRIPTION OF THE PREFERRED EMBODIMENTS

Hereinafter, embodiments of the present disclosure will be described in detail with reference to the accompanying drawings so that those skilled in the art to which the present disclosure pertains can realize the present disclosure. As those skilled in the art would realize, the described embodiments may be modified in various different ways, all without departing from the spirit or scope of the present disclosure.

The exemplary embodiments of the present disclosure will be understood more fully from the detailed description given below and from the accompanying drawings of various embodiments of the invention, which, however, should not be taken to limit the invention to the specific embodiments, but are for explanation and understanding only.

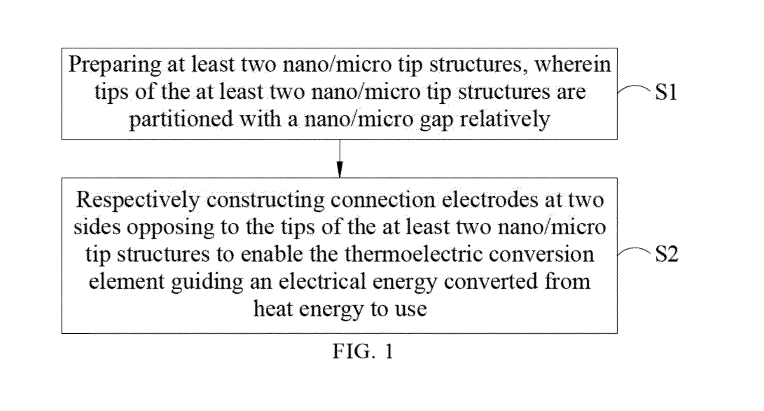

Please refer to FIG. 1 which is a flow chart of a manufacturing process of a thermoelectric conversion element in accordance with the present disclosure. As shown in the FIG., at least two nano/micro tip structures are prepared in step S1. Tips of the at least two nano/micro tip structures are partitioned into a nano/micro gap relatively. The tips of the at least two nano/micro tip structures are arranged relatively or alternately to form the nano/micro gap. The interval of the gap may be nanoscale or micron scale, and when the interval of the applied gap is smaller than 900 mm, a better thermoelectric effect is provided.

In step S2, connection electrodes are respectively constructed at two sides opposing to the tips of the at least two nano/micro tip structures to enable the thermoelectric conversion element guiding an electrical energy converted from heat energy to use.

To be precise, the nano/micro gap is used to impede the heat conducting path of the thermoelectric material to lower the thermal conductivity coefficient k to a minimum so as to promote the figure of merit ZT.

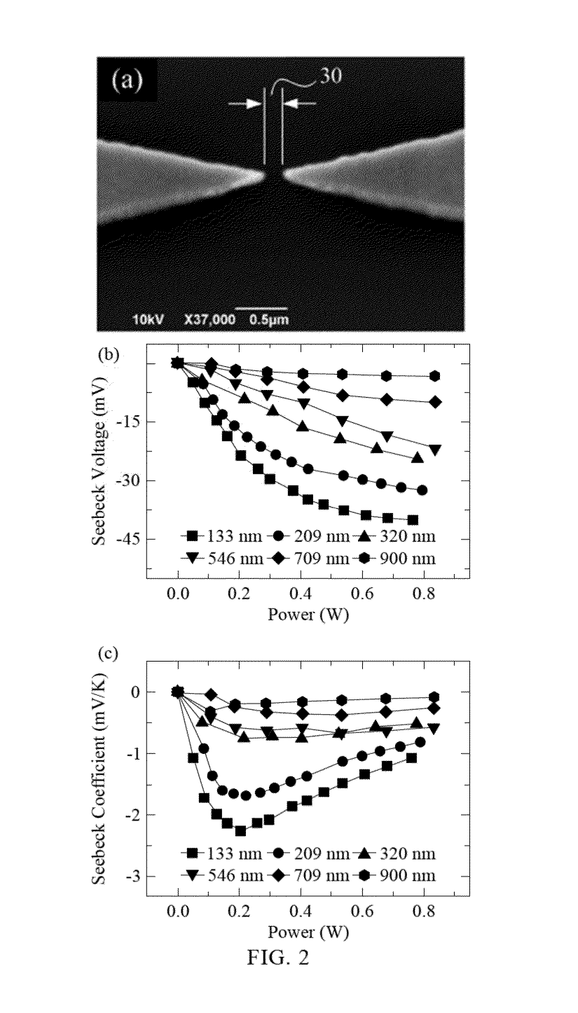

Please refer to FIG. 2 which is an experimental data diagram of a manufacturing process of a thermoelectric conversion element of the first embodiment in accordance with the present disclosure. The first embodiment discusses the interval of the nano/micro gap 30, and part (a) of FIG. 2 is a SEM diagram showing that tips of the two nano/micro tip structures are partitioned with the nano/micro gap 30. The tip at the end of the nano/micro tip structure enables the electrons jumping and being transmitted easily to the tip of next nanostructure.

Parts (b) and (c) of FIG. 2 are the curve diagrams showing the thermal electromotive force and thermoelectric coefficient of the nano/micro gap. As far as the thermoelectric conversion element in the same nano/micro gap 30 is concerned, when the heating power enhances, the absolute value of the thermal electromotive force promotes simultaneously. And in the same heating source, when the nano/micro gap 30 becomes narrower, the absolute value of the thermal electromotive force promotes as well. The reason can be inferred that when the nano/micro gap 30 becomes narrower, percentage of electrons jumping from a hot end to a cold end becomes higher such that the thermoelectric effect is enhanced. The thermoelectric effect of the thermoelectric conversion element is the least in the widest gap of 900 nm, and when the power of the heating end is close to 0.8 W, the thermoelectric coefficient is about −0.0862 mV/K. Compared with the conventional thermoelectric conversion element, the thermoelectric effect of the present disclosure goes beyond a triple of magnitude order.

Moreover, according to the diversity of the thermoelectric conversion elements with different gaps it can be found that the structure of the thermoelectric conversion element has the optimal thermoelectric effect under the specific temperature difference. When the nano/micro gap 30 is 133 nm and the heating power is 0.206 W, the maximum thermoelectric coefficient of about −2.207 mV/K is provided. With the same heating power by 900 nm, the thermoelectric effect of the nano/micro gap 30 is about −0.196 MV/K and the thermoelectric conversion element having a narrower gap is 11.26 times compared with the thermoelectric conversion element having a wider gap.

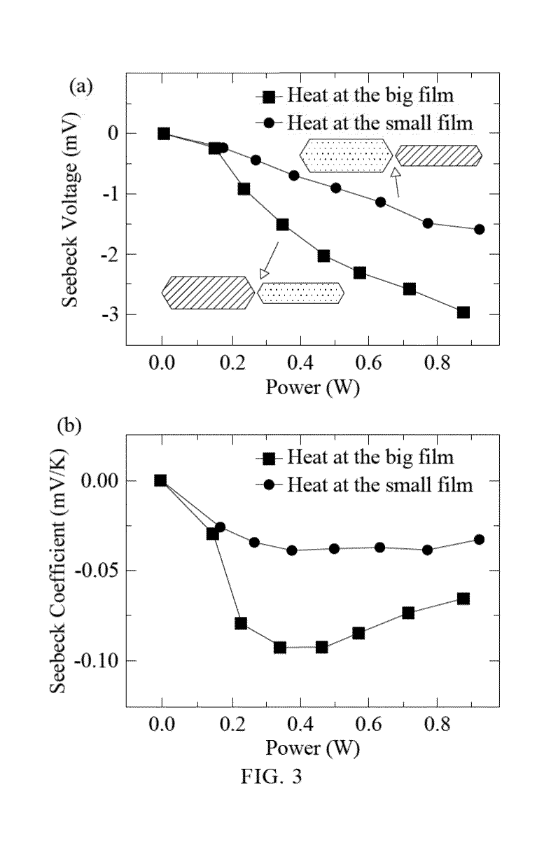

Please refer to FIG. 3 which is an experimental data diagram of a manufacturing process of a thermoelectric conversion element of the second embodiment in accordance with the present disclosure. The second embodiment is to discuss whether the different sizes of the nanostructure affect the thermoelectric effect. For example, a nano/micro tip structure with a larger area and has major axis 30 μm and minor axis 3 μm, as well as a nano/micro tip structure with a smaller area and has major axis 30 μm and minor axis 1 μm are prepared. The thickness of both nano/micro tip structures is 100 nm. Left and right ends are respectively arranged with heating line to exchange the hot end and the cold end of the thermoelectric conversion element.

As shown in parts (a) and (b) of FIG. 3, the curves of both the thermal electromotive force and thermoelectric coefficient demonstrate that if the nano/micro tip structure with a larger area is served as the hot end, the thermoelectric effect is better than the nano/micro tip structure with a smaller area. The reason is because the nano/micro tip structure with a larger area can be excited and the amount of electrons in thermal ionization is higher, and the better thermoelectric effect is thereby produced. When the heating power is about 0.381 W, the thermoelectric coefficient reaches to a maximum value, and the thermoelectric coefficients of the nano/micro tip structures having different areas are respectively −0.0927 and −0.0389 mV/K. The difference is 2.38 times.

Furthermore, the present disclosure is to utilize the disclosed nano/micro gap 30 to impede the heat conducting path of the thermoelectric material such that the hot carrier of the thermoelectric material is impeded so as to reduce the thermal conductivity coefficient k of the thermoelectric material. When the thermal conductivity coefficient k reduces, the thermoelectric effect enhances. In addition, the preceding embodiments 1 and 2 have pointed out that the thermoelectric effect of the thermoelectric conversion element applied in the present disclosure is indeed much higher than the conventional one.

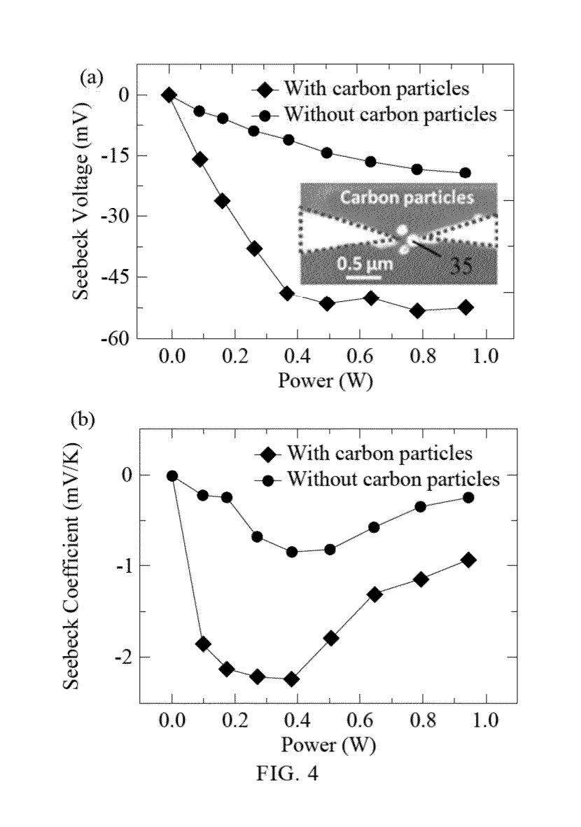

Please refer to FIG. 4 which is an experimental data diagram of a manufacturing process of a thermoelectric conversion element of the third embodiment in accordance with the present disclosure. The third embodiment takes the electrical conductivity into account. A nano additive 35 is added in the nano/micro gap, wherein the nano additive is served as a medium for electrons jumping and being transmitted so as to increase electrical conductivity of the element. In practice, the nano additive 35 includes nanoparticles, conductive media, organic particles, inorganic particles or a combination thereof. The present embodiment utilizes the carbon nano particles as the nano additive 35 to discuss the change of the thermoelectric effect. As shown in parts (a) and (b) of FIG. 4, when the heating power is 0.381 W, the thermoelectric effect increases to a maximum, which is about 2.68 times when there is no carbon nano particles added.

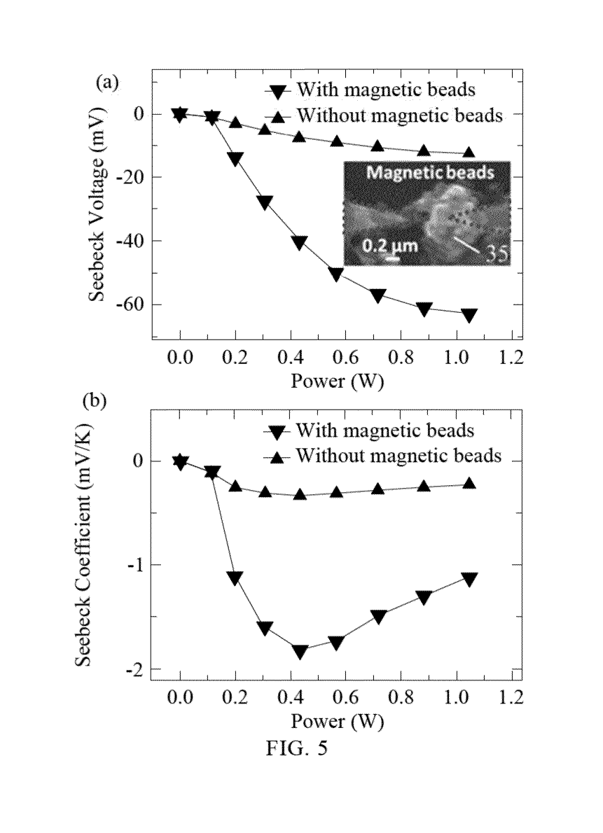

Please refer to FIG. 5 which an experimental data diagram of a manufacturing process of a thermoelectric conversion element of the fourth embodiment in accordance with the present disclosure. In the fourth embodiment, the nano particle characterized of conductive property is served as the nano additive 35 and then is added in the nano/micro gap 30 between two nano/micro structures. In the present embodiment, the Fe3O4 nano particles are placed in the nano/micro gap 30. As shown in parts (a) and (b) of FIG. 5, the curves of both the thermal electromotive force and thermoelectric coefficient of the nano particles having Fe3O4 are better than that without the Fe3O4 nano particles. When the heating power is 0.432 W, the thermoelectric effect reaches to a maximum value, which is about 5.35 times when there is no Fe3O4 nano particles added.

To be precise, embodiments 3 and 4 have shown that adding the nano additive 35 in the nano/micro gap 30 is able to obviously enhance the conductivity of the thermoelectric conversion element disclosed in the present disclosure. The reason can be inferred that the presence of the nano particles is served as a medium to enable the electrons moving from the hot end to the cold end more easily through thermionic emission so as to increase the amount of the passed electrons.

Moreover, as the disclosed thermoelectric conversion element having nano/micro gap is of discontinuous structure, the transmitting path of the hot carrier of the thermoelectric material is impeded such that the thermal conductivity coefficient is reduced. In addition, even though the nano particles are served as the medium for the electrons jumping and being transmitted, the transmitting path of the electrons can be maintained and the speed of transmission of the electrons can be enhanced such that the conductivity is thereby promoted and the thermal electromotive force and thermoelectric coefficient are increased.

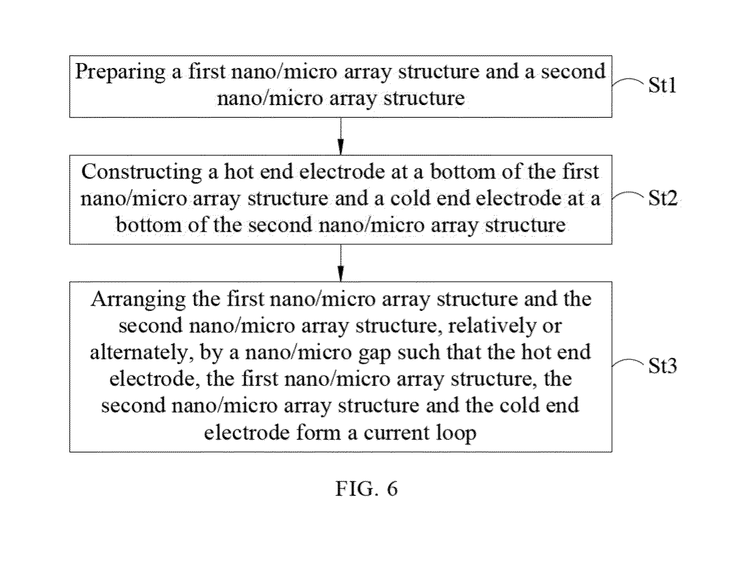

Please refer to FIG. 6 which is a flow chart of a manufacturing process of a thermoelectric conversion element with a multi-dimensional nano/micro array in accordance with the present disclosure. According to the preceding experiment results, the present disclosure is to disclose utilizing the concept of a multi-dimensional nano/micro array to provide a manufacturing process of a thermoelectric conversion element with a multi-dimensional nano/micro array. In step St1, a first nano/micro array structure and a second nano/micro array structure are prepared, wherein the first nano/micro array structure and the second nano/micro array structure may be made of the thermoelectric materials such as compound of rare-earth element, Si-based materials, III-V group semiconductor material, ferromagnetic material, metallic material and so on according to the practical need.

The ends of the first nano/micro array structure and the second nano/micro array structure may be shaped as a tip which may limit the heat conducting path so as to change the thermal conductivity coefficient. Moreover, the nano/micro array structure has the advantage of discharge effect by means of the tip at the end, so as to enhance the efficiency of the electrons transmission.

In step St2, a hot end electrode is constructed at a bottom of the first nano/micro array structure and a cold end electrode is constructed at a bottom of the second nano/micro array structure. Electrodes are respectively connected at the bottom of the nano/micro array structure, and the electrodes may be defined as hot end electrode and cold end electrode according to the temperature variation of the set environment.

In step St3, the first nano/micro array structure and the second nano/micro array structure are arranged relatively or alternately, by a nano/micro gap such that the hot end electrode, the first nano/micro array structure, the second nano/micro array structure and the cold end electrode form a current loop. The current loop may transmit the electric power generated by the temperature variation of the set environment, and may output the electrical power through a connected external device. The temperature gradient may convert the heat power of the initial energy into the other feasible energies.

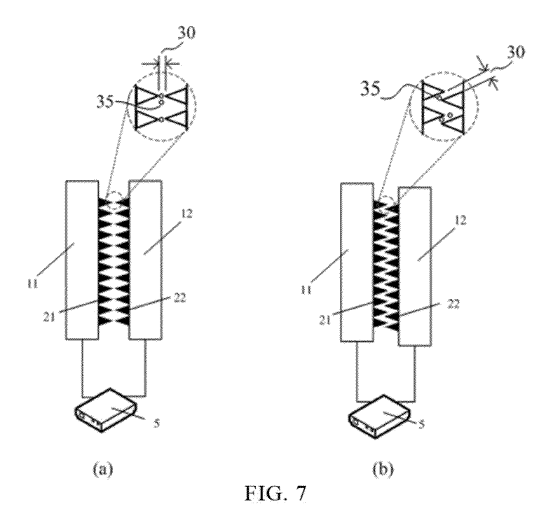

Please refer to FIG. 7 which is a schematic diagram of a thermoelectric conversion element with a multi-dimensional nano/micro array in accordance with the present disclosure. As shown in the FIG. 7, the thermoelectric conversion element with the multi-dimensional nano/micro array 100 includes a hot end electrode 11, a cold end electrode 12, a first nano/micro array structure 21 and a second nano/micro array structure 22. The hot end electrode 11 is connected with the first nano/micro array structure 21 and electrically connected with an external device 5. Likewise, the cold end electrode 12 is connected with the second nano/micro array structure 22 and electrically connected with the external device 5 to form a current loop. And the external device 5 outputs/inputs the related electrical signal.

The first nano/micro array structure 21 and the second nano/micro array structure 22 are arranged relatively or alternately, by a nano/micro gap, wherein the end of the nano/micro structure may be a tip which is able to effectively reduce the thermal conductivity coefficient and enhance the electrical conductivity.

In practice, as the first nano/micro array structure 21 and the second nano/micro array structure 22 are discontinuous structures, the entire thermoelectric effect may not be affected even slight contacts occur in the assembling process. The reason is that even if the two nano/micro array structures contact with each other, structures thereof are not the continuous structures made of single material, and thus the heat conducting path of the thermoelectric material is impeded. Moreover, the two nano/micro array structures contact with each other by point-to-point, the transmission of the hot carrier is not as smooth as the continuous. structure performs, and as a result the thermal conductivity coefficient of the thermoelectric material is reduced and the thermoelectric effect is thereby enhanced.

Furthermore, the nano additive 35 may be added in the nano/micro gap 30, wherein the nano additive is served as a medium for electrons jumping so as to increase electrical conductivity of the element. The nano additive may include nanoparticles, conductive media, organic particles, inorganic particles or a combination thereof.

In practice, the thermoelectric conversion element with the multi-dimensional nano/micro array 100 may be disposed on heat dissipating fins. The hot end electrode 11 is attached on the heat dissipating fins, and the cold end electrode is disposed on the other heat dissipating fins that are relatively at lower temperature. By means of the temperature difference and the thermoelectric conversion element with the multi-dimensional nano/micro array 100, the generated power can be transmitted to the external device 5 to be stored and used.

To be more precise, the thermoelectric conversion element with the multi-dimensional nano/micro array disclosed in the present disclosure may be selectively arranged in the apparatus having temperature gradient according to the different environment. As a result, other than dissipating the waste heat generated by the apparatus, the thermoelectric conversion element with the multi-dimensional nano/micro array can further convert the waste heat into the other feasible energies, such that the demand of the electric power for the apparatus can be reduced greatly and the burden to the environment caused by human can be decreased so as to accomplish the purpose of saving energy.

While the means of specific embodiments in present disclosure has been described by reference drawings, numerous modifications and variations could be made thereto by those skilled in the art without departing from the scope and spirit of the invention set forth in the claims. The modifications and variations should in a range limited by the specification of the present disclosure.

What is claimed is:

1. A manufacturing process of a thermoelectric conversion element, comprising:
preparing at least two nano/micro tip structures, wherein tips of the at least two nano/micro tip structures are partitioned with a nano/micro gap relatively, and
respectively constructing connection electrodes at two sides opposing to the tips of the at least two nano/micro tip structures to enable the thermoelectric conversion element guiding an electrical energy converted from heat energy to use.

2. The manufacturing process of the thermoelectric conversion element of claim 1, wherein the tips of the at least two nano/micro tip structures are arranged relatively or alternately to form the nano/micro gap.

3. The manufacturing process of the thermoelectric conversion element of claim 1, further comprising: adding a nano additive in the nano/micro gap, wherein the nano additive is served as a medium for electrons jumping and being transmitted so as to increase electrical conductivity of the thermoelectric conversion element.

4. The manufacturing process of the thermoelectric conversion element of claim 3, wherein the nano additive comprises nanoparticles, conductive media, organic particles, inorganic particles or a combination thereof.

5. A manufacturing process of a thermoelectric conversion element with a multi-dimensional nano/micro array, comprising:
preparing a first nano/micro array structure and a second nano/micro array structure;
constructing a hot end electrode at a bottom of the first nano/micro array structure and a cold end electrode at a bottom of the second nano/micro array structure, and
arranging the first nano/micro array structure and the second nano/micro array structure, relatively or alternately, by a nano/micro gap such that the hot end electrode, the first nano/micro array structure, the second nano/micro array structure and the cold end electrode form a current loop.

6. The manufacturing process of the thermoelectric conversion element with the multi-dimensional nano/micro array of claim 5, further comprising:
adding a nano additive in the nano/micro gap, wherein the nano additive is served as a medium for electrons jumping and being transmitted so as to increase electrical conductivity of the thermoelectric conversion element with the multi-dimensional nano/micro array.

7. The manufacturing process of the thermoelectric conversion element with the multi-dimensional nano/micro array of claim 6, wherein the nano additive comprises nanoparticles, conductive media, organic particles, inorganic particles or a combination thereof.

8. A thermoelectric conversion element with a multi-dimensional nano/micro array, comprising:
a hot end electrode electrically connected to an external device,
a cold end electrode electrically connected to the external device,
a first nano/micro array structure made of a thermoelectric material and disposed on the hot end electrode,
a second nano/micro array structure made of the thermoelectric material and disposed on the cold end electrode,
wherein the first nano/micro array structure and the second nano/micro array structure are arranged relatively or alternately, by a nano/micro gap, and the external device receives an electric current generated by a temperature variation of the thermoelectric conversion element with the multi-dimensional nano/micro array.

9. The thermoelectric conversion element with the multi-dimensional nano/micro array of claim 8, wherein the nano/micro gap is added with a nano additive and the nano additive is served as a medium for electrons jumping so as to increase electrical conductivity of the element.

10. The thermoelectric conversion element with the multi-dimensional nano/micro array of claim 9, wherein the nano additive comprises nanoparticles, conductive media, organic particles, inorganic particles or a combination thereof.
